(19) United States
(12) Patent Application Publication
(10) Pub. No.: US 2007/0115066 A1
(43) Pub. Date: May 24, 2007

(54) Radio-frequency amplifier and radio-frequency wireless communication apparatus

(76) Inventors: Hiroyasu Matsuzaki, Yokohama-shi (JP); Kazutaka Mukaiyama, Sagamihara-shi (JP); Koichi Sakamoto, Otsu-shi (JP)

Correspondence Address: DICKSTEIN SHAPIRO LLP, 1177 AVENUE OF THE AMERICAS (6TH AVENUE), NEW YORK, NY, 10036-2714, US

(21) Appl. No.: 10/580,461

(22) PCT Filed: Nov. 10, 2004
(86) PCT No.: PCT/JP04/16664

§ 371 Date: May 25, 2006

(30) Foreign Application Priority Data
Dec. 5, 2003 (JP) 2003-407399

(51) Int. Cl. H03F 3/14

(52) U.S. Cl. 330/307

(57) ABSTRACT

A radio-frequency amplifier having an input-side line portion and an output-side line portion including an input slot line and an output slot line extending in parallel formed on a substrate. In a connecting portion of a transistor, a gate electrode G, a drain electrode D, and source electrodes S are arranged in a coplanar manner. The gate electrode G, the drain electrode D, and the source electrodes S are connected to DC electrodes and a ground electrode, respectively, in a flip chip method via bumps, so that the orientation of the slot lines is perpendicular to the orientation of the gate electrode G and the drain electrode D. Preferably, the source electrodes S of the transistor are connected via an air bridge.

### FIELD OF THE INVENTION

The present invention relates to a radio-frequency amplifier and a radio-frequency wireless communication apparatus used in a millimeter-wave band or a microwave band.

### BACKGROUND OF THE INVENTION

Using slot lines in this type of radio-frequency amplifier enables easy connection with a semiconductor device or the like and propagation of a well-balanced radio-frequency signal. For this reason, slot lines have been used as input and output lines for a radio-frequency signal or part of a module in recent years, as disclosed in Patent Documents 1 to 3 (see Patent Documents 1 to 3).

FIG. 21 is a schematic plan view showing an amplifier disclosed in Patent Document 1.

In this amplifier, conductors 101 and 102 on a substrate 100 define an input slot 200, conductors 103 and 104 define an output slot 201, and a conductor 105 is placed between the input and output slots 200 and 201, which extend along an almost straight line. Gate electrodes G of FETs 301 and 302 in a chip 300 connect to the conductors 101 and 102, respectively; drain electrodes D thereof connect to the conductors 103 and 104, respectively; and source electrodes S thereof connect to the conductor 105. That is, the orientation of arrangement of the gate electrode G and the drain electrode D of each FET 301 (302) is parallel with the input and output slots 200 and 201. A microwave signal from the input slot 200 is amplified by the FETs 301 and 302 and is output to the output slot 201.

Patent Document 1: PCT Japanese Translation Patent Publication No. 2001-501418

Patent Document 2: PCT Japanese Translation Patent Publication No. 2000-500310

Patent Document 3: Japanese Unexamined Patent Application Publication No. 01-095602

However, in the above-described amplifier, in which the orientation of arrangement of the gate electrode G and the drain electrode D of each FET 301 (302) is parallel with the input and output slots 200 and 201, if a microwave signal is in a TE mode or the like, the direction of a magnetic field of the microwave signal propagating through the input and output slots 200 and 201 is different by almost 90 degrees from the direction of a magnetic field of a current flowing through the gate electrode G and the drain electrode D of each FET 301 (302). Thus, energy loss occurs when the magnetic field propagates from the input slot 200 to the gate electrode G side of each FET 301 (302) and when the magnetic field propagates from the drain electrode D side to the output slot 201. Accordingly, significant insertion loss is caused by the FETs 301 and 302 disadvantageously.

In each FET 301 (302) applied in this amplifier, the gate electrode G, the drain electrode D, and the source electrode S are dispersed. Therefore, when each FET 301 (302) itself is to be measured, each electrode needs to be separately measured with a probe in order to evaluate the characteristic thereof. In that case, the measured characteristic may be different from a characteristic obtained when each FET 301 (302) is mounted. Furthermore, since the direction of a magnetic field of a microwave signal propagating through the input and output slots 200 and 201 is different from the direction of a magnetic field of each FET 301 (302) when the FETs are mounted, the electromagnetic field mode input to each FET 301 (302) when each FET 301 (302) itself is measured is different from the electromagnetic field mode input to each FET 301 (302) when the FETs are mounted, so that designing a circuit on the basis of a measurement result is difficult.

This problem arises also in the techniques according to the above-mentioned Patent Documents 2 and 3.

### SUMMARY OF THE INVENTION

The present invention has been made to solve the above-described problem and an object thereof is to provide a radio-frequency amplifier and a radio-frequency wireless communication apparatus enabling reduction of insertion loss caused by a transistor and precise circuit design based on a measurement result.

In order to solve the above-described problem, the radio-frequency amplifier according to an embodiment of the invention includes an input-side line portion which is formed on a substrate, which has an input slot line whose one end is shorted, and which is used to input an electromagnetic-field-mode signal whose magnetic field is parallel to the input slot line into the input slot line; an output-side line portion including an output slot line which is substantially parallel to the input slot line and whose one end is shorted; and a transistor which includes a coplanar connecting portion in which source electrodes are arranged on both sides of a gate electrode and a drain electrode arranged along a straight line and which is mounted on the substrate such that the gate electrode is positioned on the input slot line side, that the drain electrode is positioned on the output slot line side, and that the orientation of arrangement of the gate electrode and the drain electrode is perpendicular to the input slot line and the output slot line.

With this configuration, an input signal propagates through the input slot line and enters the transistor. Then, the signal is processed in the transistor, reaches the output slot line, and propagates through the output slot line to be output therefrom. In the transistor, the gate electrode, the drain electrode, and the both source electrodes are arranged in a coplanar manner, so that all of the electrodes can be measured at one time with a probe. A coplanar electromagnetic field mode is induced in the mounted transistor, and thus the electromagnetic field mode input to the mounted transistor is the same as the electromagnetic field mode measured in the transistor itself. Furthermore, a signal input to the input slot line of the input-side line portion is a signal of an electromagnetic field mode in which the magnetic field is parallel to the input slot line, and the orientation of arrangement of the gate electrode and the drain electrode of the transistor is perpendicular to the input slot line and the output slot line. Thus, the directions of magnetic fields of a microwave signal propagating through the input slot line, the transistor, and the output slot line are the same.

In a further embodiment of the radio-frequency amplifier according to the present invention, the input-side line portion includes the input slot line, a first DC cut line which branches off at almost 90 degrees from the input slot line to an edge of the substrate and which has a short stub of a predetermined length at the middle thereof, and a second DC cut line which branches off at a point far from the one end of the input slot line relative to the first DC cut line to the edge of the substrate and which has a short stub of a predetermined length at the middle thereof. The output-side line portion includes the output slot line, a third DC cut line which branches off from the output slot line in the direction opposite to the first DC cut line to an edge of the substrate and which has a short stub of a predetermined length at the middle thereof, and a fourth DC cut line which branches off at a point far from the one end of the output slot line relative to the third DC cut line in the direction opposite to the second DC cut line to the edge of the substrate and which has a short stub of a predetermined length at the middle thereof. The transistor is mounted on the substrate such that the gate electrode of the connecting portion is connected to a first DC electrode separated by the first DC cut line and the second DC cut line of the input-side line portion and that the drain electrode is connected to a second DC electrode separated by the third DC cut line and the fourth DC cut line of the output-side line portion, so that the orientation of arrangement of the gate electrode and the drain electrode is perpendicular to the input slot line and the output slot line, and such that the both source electrodes are connected to a ground electrode separated by the input slot line, the first DC cut line, the output slot line, and the third DC cut line.

With this configuration, the gate electrode of the transistor is connected to the first DC electrode separated by the first DC cut line and the second DC cut line of the input-side line portion, whereas the drain electrode is connected to the second DC electrode separated by the third DC cut line and the fourth DC cut line of the output-side line portion. Accordingly, a biasing DC can be directly supplied from the gate electrode and the drain electrode serving as the hot-side of a coplanar line.

Preferably, the gate electrode and the drain electrode of the transistor are placed before the one ends of the input slot line and the output slot line, respectively, by a distance of ¼ wavelength.

With this configuration, the positions of the input slot line and the output slot line corresponding to the positions where the gate electrode and the drain electrode of the transistor are arranged are electrically open.

According to yet another embodiment of the invention, the short stubs of the first and second DC cut lines are placed at positions of ¼ wavelength from branch points of the input slot line, and the short stubs of the third and fourth DC cut lines are placed at positions of ¼ wavelength from branch points of the output slot line.

With this configuration, the branch points between the input slot line and the first and second DC cut lines and the branch points between the output slot line and the third and fourth DC cut lines are electrically shorted.

Preferably, an air bridge to electrically connect the both source electrodes is provided in the connecting portion of the transistor.

With this configuration, the both source electrodes of the transistor are at the same potential.

According to a further embodiment of the present invention, a part of the input slot line between the first DC cut line and the second DC cut line is curved toward the output slot line side and a part of the output slot line between the third DC cut line and the fourth DC cut line is curved toward the input slot line side so that pad portions are formed on the first and second DC electrodes. The gate electrode and the drain electrode are connected to the pad portions of the first and second DC electrodes, respectively.

With this configuration, the pad portions of the first and second DC electrodes are protruded while facing each other, so that the connecting point between the pad portion of the first DC electrode and the gate electrode can be placed close to the connecting point between the ground electrode and the source electrode, and that the connecting point between the pad portion of the second DC electrode and the drain electrode can be placed close to the connecting point between the ground electrode and the source electrode.

According to another embodiment of the present invention, the connecting portion of the transistor faces the substrate, and the gate electrode, the drain electrode, and the both source electrodes are connected to the first and second DC electrodes and the ground electrode, respectively, in a flip chip method using bumps.

With this configuration, the distances between the connecting points of the source electrodes on the substrate and the connecting points of the gate electrode and the drain electrode on the substrate can be shortened.

According to a further embodiment of the invention, the connecting portion of the transistor is oriented to the side opposite to the substrate. The gate electrode and the drain electrode are connected to the first and second DC electrodes, respectively, via wires, and the both source electrodes are connected to the ground electrode via through holes provided in the transistor.

With this configuration, the distance between the connecting point between one source electrode and the ground electrode and the connecting point between the other source electrode and the ground electrode becomes short, so that the both source electrodes on the transistor are at almost the same potential.

According to the another embodiment of the invention, the connecting portion of the transistor is oriented to the side opposite to the substrate. The gate electrode, the drain electrode, and the both source electrodes are connected to the pad portions of the first and second DC electrodes and the ground electrode, respectively, via through holes provided in the transistor.

With this connection via through holes, the connecting point between the pad portion of the first DC electrode and the gate electrode can be placed close to the connecting point between the ground electrode and the source electrode, whereas the connecting point between the pad portion of the second DC electrode and the drain electrode can be placed close to the connecting point between the ground electrode and the source electrode.

Preferably, one or more heat-dissipating through holes are provided in a portion of the substrate corresponding to a connecting position of the transistor.

With this configuration, heat generated in the transistor is dissipated through the heat-dissipating through holes.

A radio-frequency wireless communication apparatus according to the present invention includes a mixer to receive an intermediate-frequency signal and a local oscillation signal from a local oscillator through a slot line, convert the intermediate-frequency signal to a radio-frequency signal, and output the radio-frequency signal through a slot line; the radio-frequency amplifier as described above to receive the radio-frequency signal from the mixer through an input slot line of an input-side line portion and amplify the signal; and a slot antenna to transmit the radio-frequency signal output from an output slot line of an output-side line portion of the radio-frequency amplifier.

According to a further embodiment of the radio-frequency wireless communication apparatus according to the present invention, the radio-frequency wireless communication apparatus includes the radio-frequency amplifier as described above to receive a radio-frequency signal received by the slot antenna through the input slot line of the input-side line portion and amplify the radio-frequency signal; and a mixer to receive the radio-frequency signal output from the output slot line of the output-side line portion of the radio-frequency amplifier and a local oscillation signal from the local oscillator through a slot line, convert the radio-frequency signal to an intermediate-frequency signal, and output the intermediate-frequency signal through a slot line.

As described above, in the radio-frequency amplifier according to the invention, all of the electrodes can be measured at one time with a probe, so that the transistor itself can be easily measured. Further, since the electromagnetic field mode input to the mounted transistor is the same as the electromagnetic field mode obtained when the transistor itself is measured, the characteristic of the mounted transistor matches the measurement characteristic of the transistor before being mounted. Accordingly, the radio-frequency amplifier can be precisely designed on the basis of the measurement result. In addition, the directions of magnetic fields of a microwave signal propagating through the input slot line, the transistor, and the output slot line are the same, so that loss occurring when the signal enters the transistor and loss occurring when the signal is output from the transistor, that is, insertion loss of the transistor is very low.

As described above, since the first and second DC electrodes are DC-separated from the ground electrode by the first to fourth DC cut lines, the input slot line, and the output slot line, DC can be directly supplied from the first and second DC electrodes to the gate electrode and the drain electrode serving as the hot-side of a coplanar line in the mounted transistor without necessity of mounting a special element such as a lead to supply bias or multi-layering the substrate. As a result, a special jig to supply DC is not necessary, which simplifies measurement and reduces the cost.

As described above, since the positions of the input slot line and the output slot line corresponding to the positions where the gate electrode and the drain electrode of the transistor are arranged are electrically open, a signal from the input slot line can be reliably input to the gate electrode side and a signal from the drain electrode side can be reliably output to the output slot line.

As described above, since the branch points between the respective DC cut lines and the slot lines are electrically shorted, a signal propagating through the slot line can be prevented from entering any DC cut line.

As described above, since both source electrodes of the transistor are at the same potential, the coplanar mode of a signal propagating in the connecting portion is reinforced. As a result, a signal of a mode other than the coplanar mode can be prevented from being generated at the connecting portion.

As described above, since the connecting point between the pad portion of the first DC electrode and the gate electrode can be placed close to the connecting point between the ground electrode and the source electrode, and the connecting point between the pad portion of the second DC electrode and the drain electrode can be placed close to the connecting point between the ground electrode and the source electrode, a coplanar mode can be easily induced in the mounted transistor, and as a result, transmission with low loss can be maintained in a higher frequency band.

In addition, because the distances between the connecting points of the source electrodes on the substrate and the connecting points of the gate electrode and the drain electrode on the substrate can be shortened, a coplanar mode can be easily induced in the mounted transistor, and low loss can be maintained even in a high frequency band.

Further, since the distance between the connecting point between one source electrode and the ground electrode and the connecting point between the other source electrode and the ground electrode is short so that the both source electrodes on the transistor are at the same potential, a signal of other mode excited by the transistor can be suppressed. As a result, a coplanar mode can be easily induced in the mounted transistor, and thus transmission with low loss can be maintained in a higher frequency band.

Because the connecting point between the pad portion of the first DC electrode and the gate electrode can be placed close to the connecting point between the ground electrode and the source electrode, and the connecting point between the pad portion of the second DC electrode and the drain electrode can be placed close to the connecting point between the ground electrode and the source electrode, a coplanar mode can be easily induced in the mounted transistor, and as a result, transmission with low loss can be maintained in a higher frequency band. Furthermore, this configuration has an advantage in that the transistor need not be die-bonded and connected with wires.

As described above, since heat generated in the transistor is efficiently dissipated through the heat-dissipating through holes, thermal isolation of the transistor can be improved.

In the radio-frequency wireless communication apparatus according to the invention 2, the respective electronic elements are connected through slot lines parallel with each other. With this configuration, the respective elements can be smoothly connected and a signal can be transmitted with low loss by allowing the signal to propagate through the slot lines in a TE mode.

### BRIEF DESCRIPTION OF THE DRAWINGS

FIG. 1 is a perspective view showing a substrate and a transistor constituting a radio-frequency amplifier according to a first embodiment of the present invention.

FIG. 2 is a schematic plan view showing the substrate.

FIG. 3 is a schematic plan view showing a connecting portion of the transistor.

FIG. 4 is a cross-sectional view taken along the line A-A in FIG. 2 in a state where the transistor is mounted.

FIG. 5 is a partial enlarged plan view showing a connection state of the transistor.

FIG. 6 is a cross-sectional view showing an electromagnetic field distribution propagating in electrodes of the transistor.

FIG. 7 is a cross-sectional view taken along the line B-B in FIG. 2 in a state where the transistor is mounted.

FIG. 8 includes schematic plan views showing a radio-frequency amplifier used in a simulation.

FIG. 9 is a characteristic diagram showing a relationship between frequency and insertion loss.

FIG. 10 is a schematic plan view showing a radio-frequency amplifier according to a second embodiment of the present invention.

FIG. 11 is a cross-sectional view taken along the line C-C in FIG. 10.

FIG. 12 is a schematic plan view showing a radio-frequency amplifier according to a third embodiment of the present invention.

FIG. 13 is a cross-sectional view taken along the line D-D in FIG. 12.

FIG. 14 is a schematic plan view showing a radio-frequency amplifier according to a fourth embodiment of the present invention.

FIG. 15 is a cross-sectional view taken along the line E-E in FIG. 14.

FIG. 16 is a schematic plan view showing a radio-frequency amplifier according to a fifth embodiment of the present invention.

FIG. 17 is a cross-sectional view taken along the line F-F in FIG. 16.

FIG. 18 is a block diagram showing a radio-frequency wireless communication apparatus according to a sixth embodiment of the present invention.

FIG. 19 is a schematic partial plan view showing a modification of the present invention.

FIG. 20 is a schematic partial plan view showing another modification of the present invention.

FIG. 21 is a schematic plan view showing a known amplifier.

### DETAILED DESCRIPTION OF THE INVENTION

Hereinafter, a best mode for carrying out the invention is described with reference to the drawings.

### First Embodiment

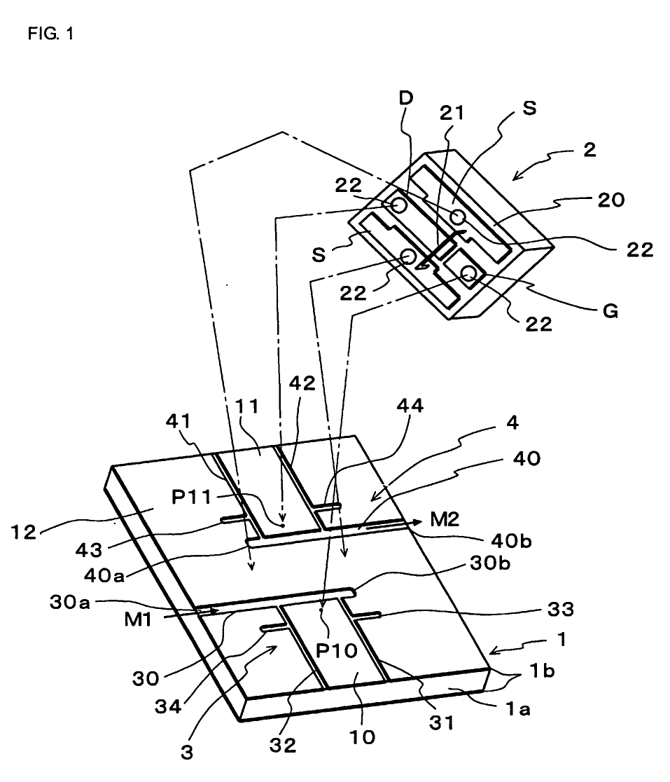

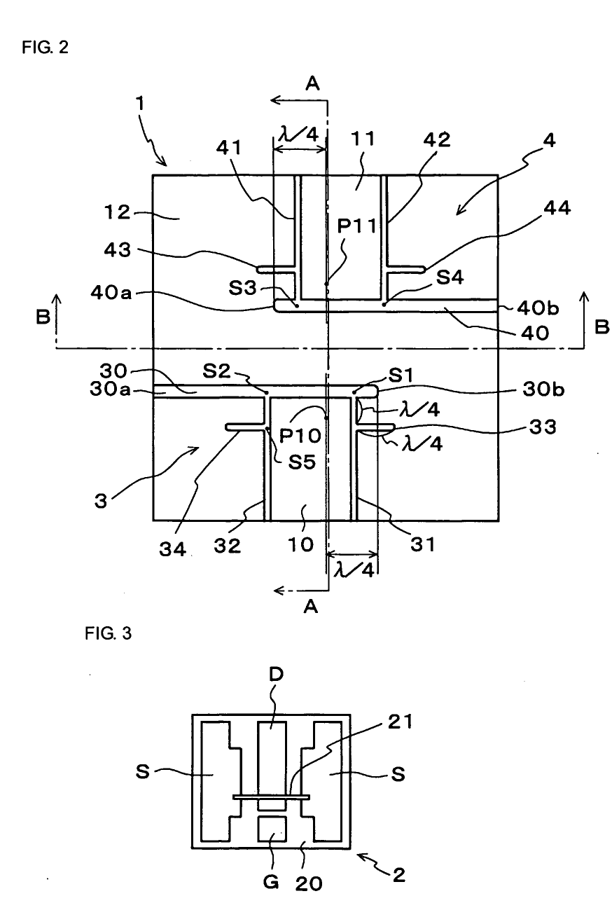

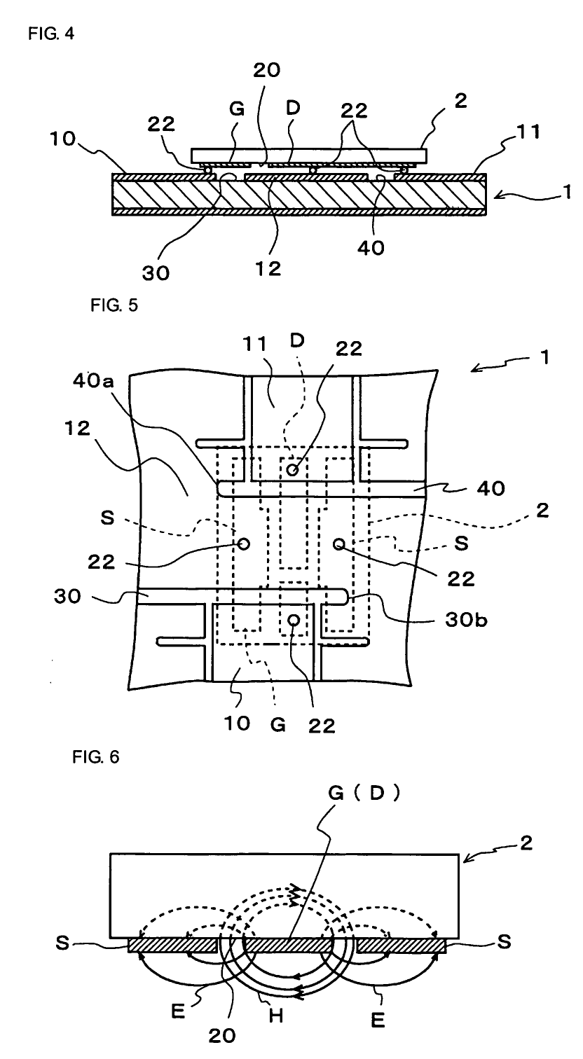

FIG. 1 is a perspective view showing a substrate and a transistor constituting a radio-frequency amplifier according to a first embodiment of the present invention; FIG. 2 is a schematic plan view showing the substrate; FIG. 3 is a schematic plan view showing a connecting portion of the transistor; FIG. 4 is a cross-sectional view taken along the line A-A in FIG. 2 in a state where the transistor is mounted; and FIG. 5 is a partial enlarged plan view showing a connection state of the transistor.

As shown in FIG. 1, the radio-frequency amplifier according to this embodiment includes the substrate 1 and the transistor 2 in a chip shape.

As shown in FIG. 1, the substrate 1 includes a dielectric plate 1a and a conductor 1b provided on both surfaces thereof. Predetermined portions of the conductor 1b are removed so that a plurality of slot lines are formed. These slot lines define an input-side line portion 3 and an output-side line portion 4.

The input-side line portion 3 includes an input slot line 30 and first and second DC (direct current) cut lines 31 and 32 which are parallel with each other. These lines 30 to 32 define a separated first DC electrode 10.

The input slot line 30 is a line to receive and transmit a microwave signal and extends straight from an open end 30a as a signal input end to a center of the substrate 1. An end 30b thereof is short-circuited.

As shown in FIG. 2, the DC cut line 31 branches off at almost 90 degrees from the input slot line 30 and opens at an edge (a lower edge in the figure) of the substrate 1. At the middle thereof, a short stub 33 whose one end is shorted is provided. The short stub 33 is placed at a position of λ/4 (λ is a wavelength of a microwave signal) from a branch point S1 of the input slot lint 30, and the length thereof is also set to λ/4.

The DC cut line 32 also branches off at almost 90 degrees from the input slot line 30 at a point before the DC cut line 31 and opens at the edge of the substrate 1. The DC cut line 32 also has a short stub 34 having a length of λ/4 at the middle. The short stub 34 is placed at a position of λ/4 from a branch point S2 of the input slot line 30.

On the other hand, as shown in FIG. 1, the output-side line portion 4 is substantially point-symmetrically placed with the input-side line portion 3 and includes an output slot line 40 and third and fourth DC cut lines 41 and 42 which are parallel with each other. These lines 40 to 42 define a separated second DC electrode 11.

The output slot line 40 is a line to output and transmit a microwave signal and is substantially parallel with the input slot line 30. Specifically, the output slot line 40 extends straight from a shorted one end 40a positioned at a center of the substrate 1 to an open end 40b as a signal output end.

As shown in FIG. 2, the DC cut line 41 branches off at almost 90 degrees from the output slot line 40 in a direction opposite to the DC cut line 31 and opens at an edge (an upper edge in the figure) of the substrate 1. At the middle thereof, a short stub 43 is provided. The short stub 43 is placed at a position of λ/4 from a branch point S3, and the length thereof is set to λ/4.

The DC cut line 42 branches off at almost 90 degrees from the output slot line 40 in a direction opposite to the DC cut line 32 behind the DC cut line 41 and opens at the edge of the substrate 1. The DC cut line 42 also has a short stub 44 having a length of λ/4 at the middle. The short stub 44 is placed at a position of λ/4 from a branch point S4.

As described above, in the substrate 1, the separated DC electrode 10 is defined by the lines 30 to 32 of the input-side line portion 3. Also, the separated DC electrode 11 is defined by the lines 40 to 42 of the output-side line portion 4. Furthermore, a separated ground electrode 12 is defined by the input slot line 30, the DC cut lien 31, the output slot line 40, and the DC cut line 41.

As shown in FIG. 1, the transistor 2 is connected to the DC electrodes 10 and 11 and to the ground electrode 12.

The transistor 2 is an active element to amplify a microwave signal input from the input slot line 30 of the input-side line portion 3 and outputs the signal to the output slot line 40 of the output-side line portion 4. In this embodiment, a FET (field-effect transistor) is applied.

As shown in FIG. 3, the transistor 2 includes a connecting portion 20 on one surface.

The connecting portion 20 includes a gate electrode G, a drain electrode D, and source electrodes S that are arranged in a coplanar manner. More specifically, the gate electrode G and the drain electrode D are placed along a straight line at the center of the connecting portion 20, and a pair of source electrodes S are placed in parallel on both sides of the gate electrode G and the drain electrode D. An air bridge 21 is provided on the pair of source electrodes S, so that the pair of source electrodes S electrically connect to each other.

In this embodiment, as indicated in FIG. 4 and with broken lines shown in FIG. 5, the transistor 2 is mounted on the substrate 1 such that the connecting portion 20 faces the substrate 1 and that the gate electrode G, the drain electrode D, and the both source electrodes S connect to the DC electrodes 10 and 11 and the ground electrode 12, respectively, via bumps 22 in a flip chip method.

Accordingly, the orientation of arrangement of the gate electrode G and the drain electrode D of the transistor 2 is perpendicular to the input slot line 30 and the output slot line 40. Further, the gate electrode G and the drain electrode D are placed at positions before the one ends 30b and 40a of the input slot line 30 and the output slot line 40 by a distance of λ/4.

Next, an effect and advantage of the radio-frequency amplifier according to this embodiment are described.

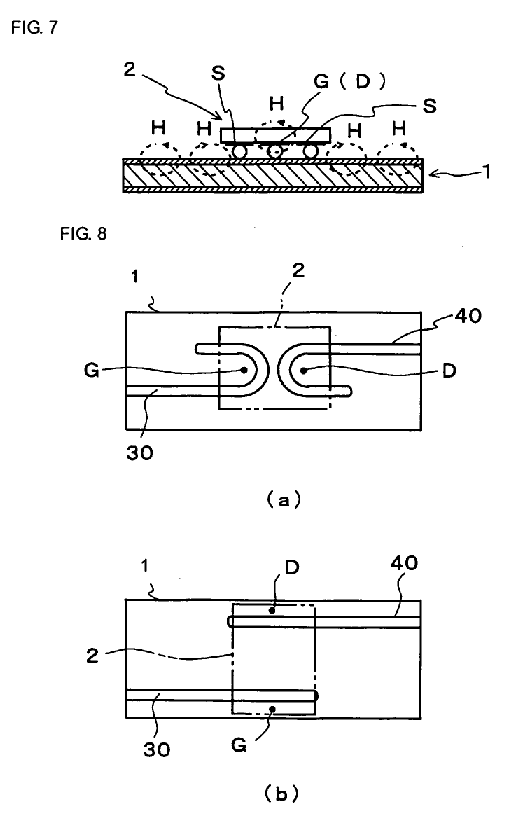

FIG. 6 is a cross-sectional view showing an electromagnetic-field distribution propagating in the electrodes of the transistor, and FIG. 7 is a cross-sectional view taken along the line B-B in FIG. 2 in a state where the transistor is mounted.

In the above-described connection state, a biasing DC current is applied to the DC electrodes 10 and 11 shown in FIG. 1 and a microwave signal M1 whose electromagnetic field mode is a TE mode is input to the input slot line 30 of the input-side line portion 3, the microwave signal M1 propagates in the input slot line 30 in a state where an electric field E is vertical to a propagation direction and a magnetic field H is parallel with the propagation direction. In other words, the magnetic field H of the microwave signal M1 propagates in a direction parallel with the input slot line 30.

This microwave signal M1 propagates in the input slot line 30 toward the transistor 2 side and reaches the branch point S2 of the DC cut line 32 (see FIG. 2). Since the length of the short stub 34 of the DC cut line 32 is λ/4, the one end of the short stub 34 is shorted, and the short stub 34 is at a position of λ/4 from the branch point S2, a branch point S5 of the short stub 34 is electrically open and the branch point S2 is electrically shorted when viewed from the input slot line 30 side. With this configuration, the microwave signal M1 cannot propagate to the DC cut line 32 side but propagates in the input slot line 30 toward the transistor 2 side, while not causing any loss.

When the microwave signal M1 reaches a connecting position P10 of the bump 22 of the gate electrode G, the input slot line 30 becomes electrically open at a position corresponding to the connecting position P10 because the one end 30b of the input slot line 30 is shorted and because the connecting position P10 of the gate electrode G is at a position of λ/4 from the one end 30b. Therefore, the microwave signal M1 does not propagate in the input slot line 30 any more but propagates to the gate electrode G and the both source electrodes S through the bumps 22.

Then, the microwave signal M1 input from the gate electrode G side is amplified in the transistor 2 and an amplified microwave signal M2 is output from the drain electrode D side. At this time, the gate electrode G and the drain electrode D function as a so-called hot-line, because the gate electrode G, the drain electrode D, and the both source electrodes S are arranged in a coplanar manner. Thus, the electromagnetic field distribution of the microwave signal M1 (M2) propagating through these electrodes is that shown in FIG. 6, in which both the electric field E and the magnetic field H of the microwave signal M1 (M2) are vertical to the propagation direction. In other words, the microwave signal propagates to the output slot line 40 side of the output-side line portion 4 in a coplanar mode (TEM) mode in the connecting portion 20.

The output microwave signal M2 that has been amplified in the transistor 2 reaches the output slot line 40 shown in FIGS. 1 and 2 through the bump 22 of the drain electrode D. Since a connecting position P11 of this bump 22 is at a position of λ/4 from the one end 40a of the output slot line 40, the output slot line 40 becomes electrically open at a position corresponding to the connecting position P11 when viewed from the open end 40b side. Thus, the microwave signal M2 does not propagate to the one end 40a side but propagates toward the open end 40b in the output slot line 40. Then, the microwave signal M2 propagates toward the open end 40b in the output slot line 40 and reaches the branch point S4 of the DC cut line 42 (see FIG. 2). In this case, as in the case of the DC cut line 31, the branch point S4 is electrically shorted when viewed from the output slot line 40 side. Thus, the microwave signal M2 cannot propagate to the DC cut line 42 side but propagates in the output slot line 40 toward the open end 40b, while not causing any loss.

Likewise, the branch points S1 and S3 of the DC cut lines 31 and 41 are electrically shorted when viewed from the slot line side, so that a leaked microwave signal M1 or M2 does not enter the DC cut lines 31 and 41.

As described above, according to the radio-frequency amplifier of this embodiment, the microwave signal M1 input into the input slot line 30 reliably propagates to reach the connecting portion 20 of the transistor 2 without causing any loss in the DC cut lines 31 and 32. Then, the microwave signal M2 amplified in the transistor 2 propagates in the output slot line 40 to be output from the open end 40b without causing any loss in the DC cut lines 41 and 42.

As shown in FIG. 6, in such a propagation state, the microwave signal propagates from the input-side line portion 3 side to the output slot line 40 side in a coplanar mode in the connecting portion 20. Furthermore, since the orientation of arrangement of the gate electrode G and the drain electrode D is perpendicular to the input slot line 30 and the output slot line 40, the directions of magnetic fields H of the microwave signal propagating through the input slot line 30, the transistor 2, and the output slot line 40 are the same, as shown in FIG. 7. As a result, loss caused when the microwave signal M1 enters the transistor 2 and loss caused when the microwave signal is output from the transistor 2, that is, insertion loss of the transistor 2 is significantly reduced.

The inventors carried out the following electromagnetic field simulation in order to verify the above-described concept.

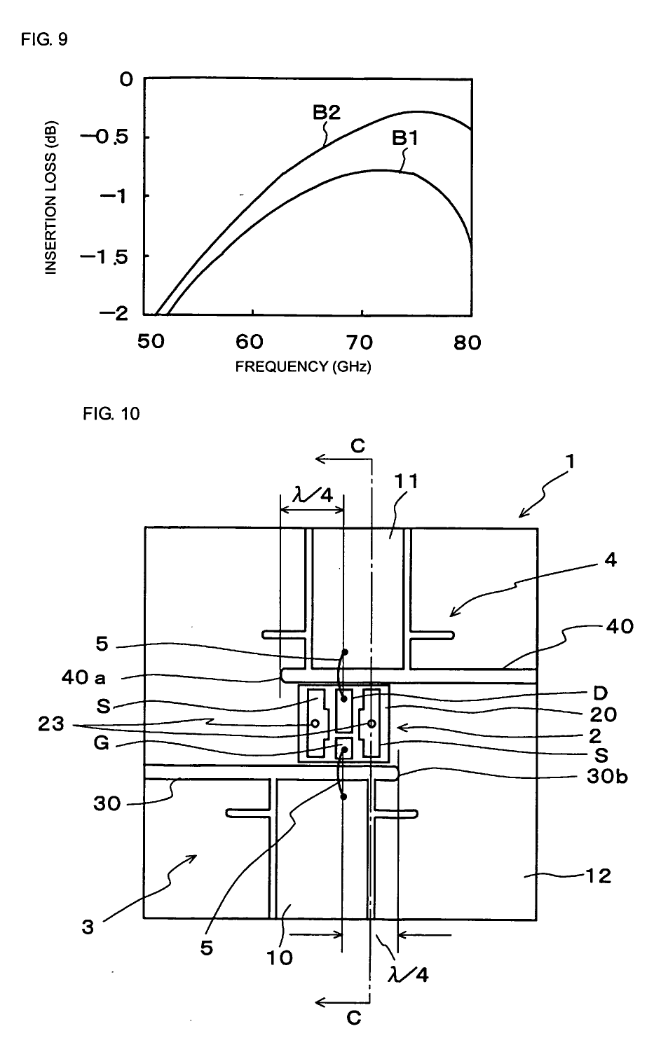

FIG. 8 includes schematic plan views of a radio-frequency amplifier used in the simulation. FIG. 8(a) shows a state where the transistor is connected such that the orientation of arrangement of the gate electrode and the drain electrode is parallel to the input slot line and the output slot line. FIG. 8(b) shows a state where the transistor is connected such that the orientation of arrangement of the gate electrode and the drain electrode is perpendicular to the input slot line and the output slot line. FIG. 9 is a characteristic diagram showing the relationship between frequency and insertion loss.

First, as shown in FIG. 8(a), the transistor 2 was connected to the substrate such that the orientation of arrangement of the gate electrode G and the drain electrode D is parallel to the input slot line 30 and the output slot line 40. In this state, a microwave signal of a 50 to 80 GHz band was input to simulate the insertion loss of the transistor 2, and as a result, a characteristic curve B1 shown in FIG. 9 was obtained. On the other hand, as shown in FIG. 8(b), the transistor 2 was connected to the substrate such that the orientation of arrangement of the gate electrode G and the drain electrode D is perpendicular to the input slot line 30 and the output slot line 40. In this state, a microwave signal of the above-described band was input to simulate the insertion loss, and as a result, a characteristic curve B2 shown in FIG. 9 was obtained. In this simulation, a FET made by forming the above-described coplanar line on GaAs (gallium arsenide) is used as the transistor 2.

As indicated by these characteristic curves B1 and B2, the insertion loss is much lower when the orientation of arrangement of the gate electrode and the drain electrode are perpendicular to the slot lines than when the orientation of arrangement of the gate electrode and the drain electrode are parallel to the slot lines.

In the transistor 2 applied to this embodiment, the gate electrode G, the drain electrode D, and the both source electrodes S are arranged in a coplanar manner, so that all of the electrodes can be measured at one time with a probe. Thus, the transistor 2 itself can be easily measured. Further, a biasing DC can be directly supplied from the gate electrode G and the drain electrode D serving as the hot-side of a coplanar line. Therefore, a special jig for supplying DC need not be prepared, which contributes to simplify the measurement and reduce the cost.

As described above, a coplanar electromagnetic field mode is induced in the mounted transistor 2. Therefore, the electromagnetic field mode input to the mounted transistor 2 is the same as the electromagnetic field mode obtained when the transistor 2 is separately measured. Thus, the characteristic of the mounted transistor 2 matches the characteristic of the transistor 2 that is not mounted. As a result, the circuit of the radio-frequency amplifier can be precisely designed on the basis of the measurement result.

Since the DC electrodes 10 and 11 are DC-separated from the ground electrode 12 by the DC cut lines 31, 32, 41, and 42, a special element such as a lead to supply bias need not be mounted and the substrate need not be multi-layered. In the mounted transistor 2, DC can be supplied from the gate electrode G and the drain electrode D serving as the hot-side of a coplanar line.

Since the both source electrodes S of the transistor 2 are electrically connected through the air bridge 21, the source electrodes S are at the same potential, so that the coplanar mode of the microwave signal propagating in the connecting portion 20 is reinforced. As a result, a signal of a mode other than the coplanar mode can be prevented from occurring in the connecting portion 20.

The transistor 2 is connected to the substrate 1 in a flip chip method by using the bumps 22. With this configuration, the distance between connecting points of the source electrodes S on the substrate and connecting points of the gate electrode G and the drain electrode D on the substrate can be shorter than the distance between respective connecting points on the substrate in a case where the source electrodes S, the gate electrode G, and the drain electrode D are connected to the substrate 1 by using wires as in die bonding. As a result, a coplanar mode is easily induced in the mounted transistor 2, so that low loss can be maintained even in a high-frequency band.

### Second Embodiment

Next, a second embodiment of the present invention is described.

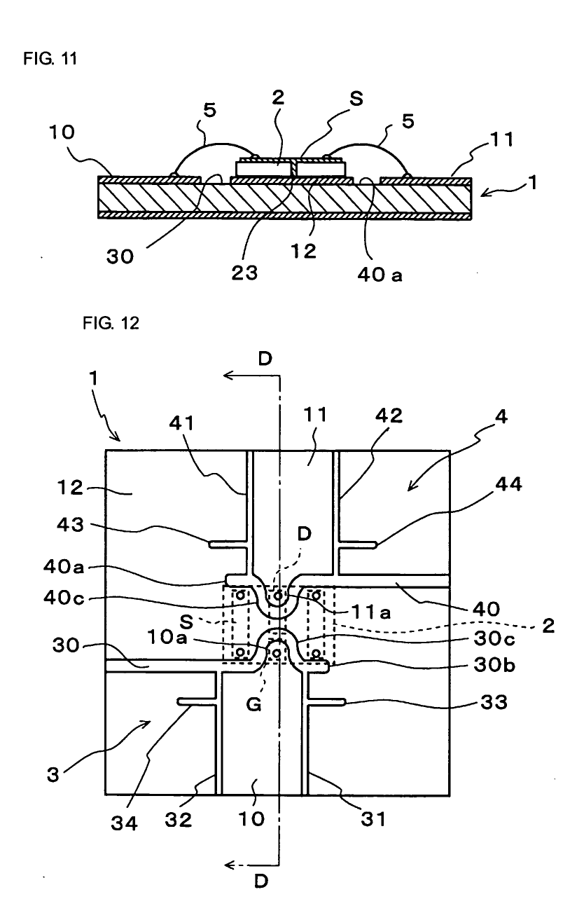

FIG. 10 is a schematic plan view showing a radio-frequency amplifier according to the second embodiment of the present invention, and FIG. 11 is a cross-sectional view taken along the line C-C in FIG. 10.

The radio-frequency amplifier according to this embodiment is different from that of the above-described first embodiment in the shape of lines on the substrate and in an attachment state of the transistor.

As shown in FIG. 10, in this embodiment, the transistor 2 is mounted in the reverse orientation between the input slot line 30 and the output slot line 40.

Specifically, as shown in FIGS. 10 and 11, the transistor 2 is mounted on the ground electrode 12 and is die-bonded with a conductive paste such that the connecting portion 20 of the transistor 2 is oriented to the side opposite to the substrate 1. The gate electrode G and the drain electrode D are set to positions before the one ends 30b and 40a of the input slot line 30 and the output slot line 40 by λ/4, respectively, and the gate electrode G and the drain electrode D connect to the DC electrodes 10 and 11, respectively, with wires 5. Further, the both source electrodes S connect to the ground electrode 12 via through holes 23 provided in the transistor 2.

The other configuration, effect, and advantage are substantially the same as those in the above-described first embodiment, and thus the corresponding description is omitted.

### Third Embodiment

Next, a third embodiment of the present invention is described.

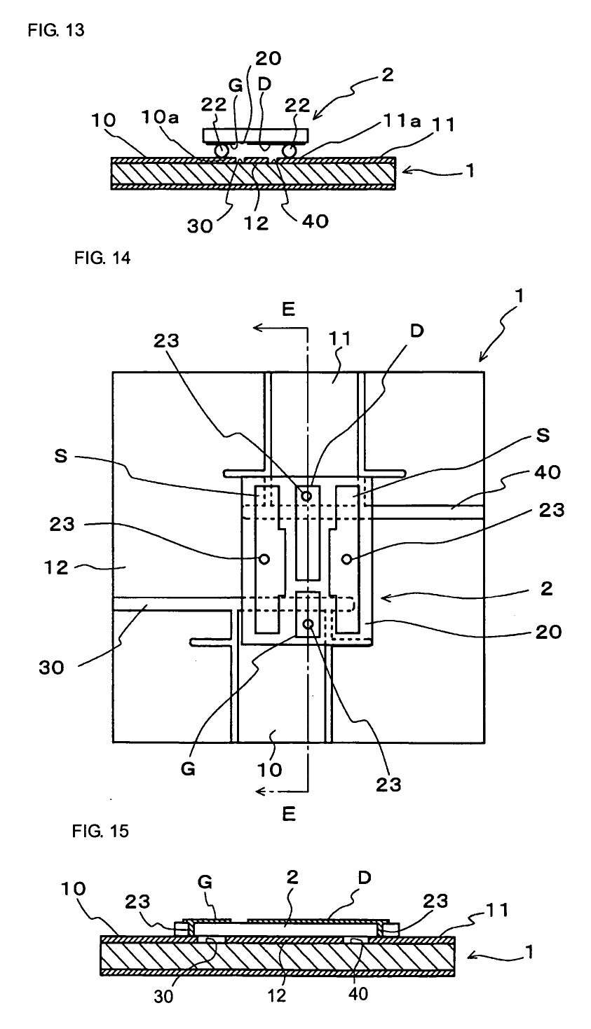

FIG. 12 is a schematic plan view showing a radio-frequency amplifier according to the third embodiment of the present invention, and FIG. 13 is a cross-sectional view taken along the line D-D in FIG. 12.

The radio-frequency amplifier according to this embedment is different from that of the above-described second embodiment in that pad portions 10a and 11a for connection with the transistor 2 are provided in the DC electrodes 10 and 11.

That is, as shown in FIGS. 12 and 13, the input slot line 30 has a curved portion 30c. Specifically, the line between the DC cut line 31 and the DC cut line 32 is curved toward the output-side line potion 4 so that the pad portion 10a is formed at an edge of the DC electrode 10. The center of the pad portion 10a is positioned before the one end 30b of the input slot line 30 by a distance of λ/4.

Also, the output slot line 40 has a curved portion 40c. That is, the line between the DC cut line 41 and the DC cut line 42 is curved toward the input slot line 30 so that the pad portion 11a is formed at an edge of the DC electrode 11. The center of the pad portion 11a is positioned away from the one end 40a by a distance of λ/4.

The transistor 2 is connected in a flip chip method such that the bump 22 of the gate electrode G is positioned at the center of the pad portion 10a of the DC electrode 10, that the bump 22 of the drain electrode D is positioned at the center of the pad portion 11a of the DC electrode 11, and that the bumps 22 of the both source electrodes S are positioned on the ground electrode 12.

The other configuration, effect, and advantage are substantially the same as those in the above-described first and second embodiment, and thus the corresponding description is omitted.

### Fourth Embodiment

Next, a fourth embodiment of the present invention is described.

FIG. 14 is a schematic plan view showing a radio-frequency amplifier according to the fourth embodiment of the present invention, and FIG. 15 is a cross-sectional view taken along the line E-E in FIG. 14.

The radio-frequency amplifier according to this embodiment is different from those of the above-described embodiments in that the transistor 2 is mounted on the substrate 1 by die-bonding and that all electrodes are connected via through holes.

Specifically, the transistor 2 is mounted over the DC electrodes 10 and 11 and the ground electrode 12 and is die-bonded with a conductive paste such that the connecting portion 20 of the transistor 2 is oriented to the side opposite to the substrate 1. Through holes 23 are provided at positions corresponding to the gate electrode G, the drain electrode D, and the both source electrodes S. The gate electrode G, the drain electrode D, and the both source electrodes S electrically connect to the DC electrodes 10 and 11 and the ground electrode 12, respectively, via these through holes 23.

The other configuration, effect, and advantage are substantially the same as those of the above-described first to third embodiments, and thus the corresponding description is omitted.

### Fifth Embodiment

Next, a fifth embodiment of the present invention is described.

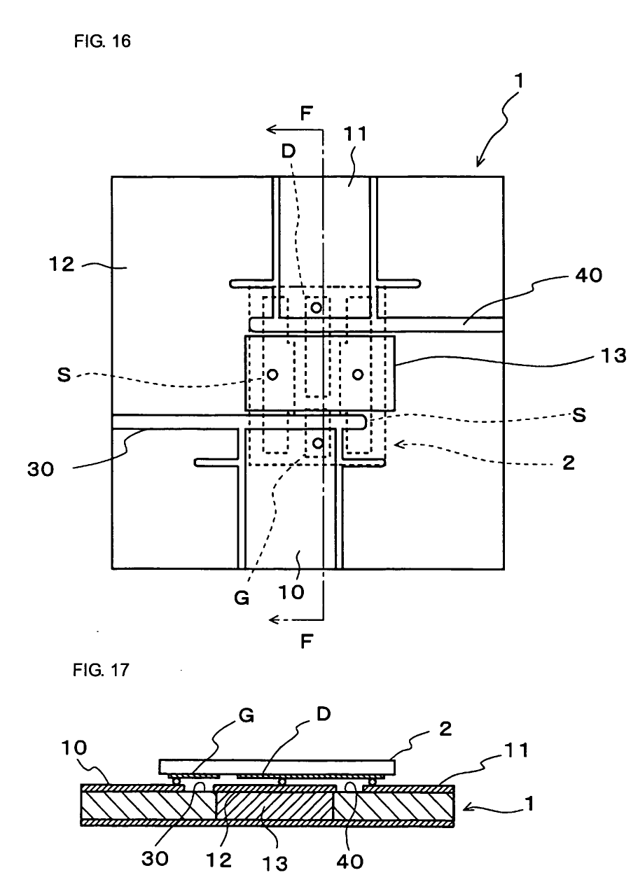

FIG. 16 is a schematic plan view showing a radio-frequency amplifier according to the fifth embodiment of the present invention, and FIG. 17 is a cross-sectional view taken along the line F-F in FIG. 16.

The radio-frequency amplifier according to this embodiment is different from those of the above-described first to fourth embodiments in that a through hole to dissipate heat of the transistor is provided in the substrate.

That is, as shown in FIGS. 16 and 17, a heat-dissipating through hole 13 is provided at a portion of the substrate 1 corresponding to the connecting portion of the transistor 2 in the radio-frequency amplifier according to the first embodiment. Specifically, the heat-dissipating through hole 13, which is rectangular in a plan view, is provided at a portion of the ground electrode 12 between the input slot line 30 and the output slot line 40 and just under the position where the transistor 2 is mounted. This heat-dissipating through hole 13 is a thermal via hole filled with a member having high thermal conductivity and has a function of transferring heat generated by the transistor 2 to the lower side of the substrate 1 so as to cool the transistor 2.

With this configuration, heat generated by the transistor 2 can be efficiently dissipated, so that thermal isolation of the transistor 2 can be improved.

The other configuration, effect, and advantage are substantially the same as those in the above-described first to forth embodiments, and thus the corresponding description is omitted.

### Sixth Embodiment

Next, a sixth embodiment of the present invention is described.

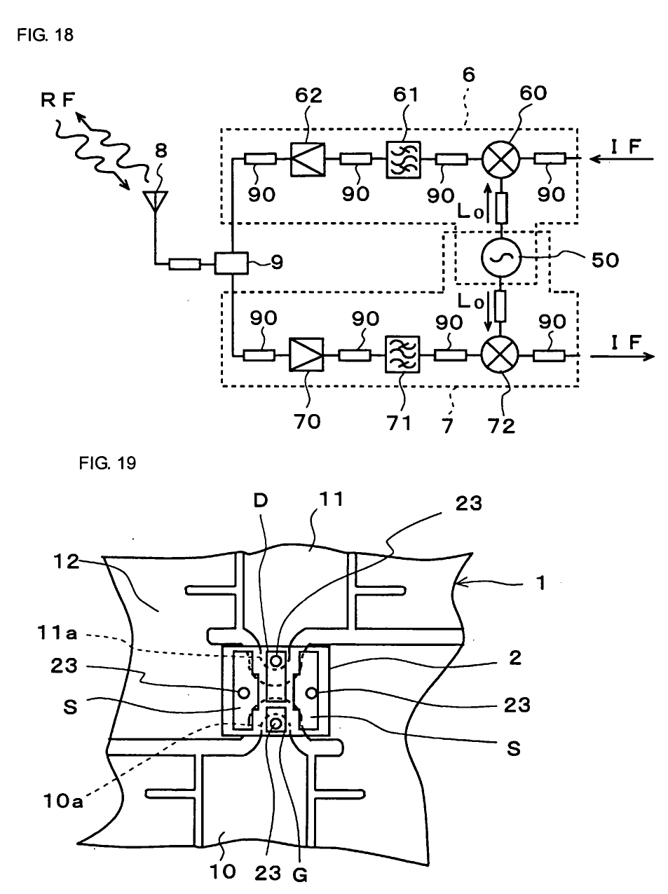

FIG. 18 is a block diagram showing a radio-frequency wireless communication apparatus according to the sixth embodiment of the present invention.

This radio-frequency wireless communication apparatus includes a transmitting unit 6, a receiving unit 7, a slot antenna 8, and a separator 9 to separate transmission and reception signals.

The transmitting unit 6 includes a mixer 60, a band-pass filter 61, and a radio-frequency amplifier 62 according to any of the above-described embodiments, which are connected through slot lines 90, and has a function of converting an intermediate-frequency signal IF to a radio-frequency signal RF and transmitting the RF signal from the slot antenna 8.

Specifically, the mixer 60 receives an intermediate-frequency signal IF and a local oscillation signal Lo from a local oscillator 50 through the slot line 90, converts the intermediate-frequency signal IF to a radio-frequency signal RF, and outputs the radio-frequency signal RF to the band-pass filter 61. Then, the band-pass filter 61 filters the radio-frequency signal RF and outputs the signal to the radio-frequency amplifier 62. The radio-frequency amplifier 62 receives the radio-frequency signal RF through the input slot line 30 of the input-side line portion 3 and amplifies the signal. Then, the radio-frequency amplifier 62 transmits the amplified radio-frequency signal RF to the slot antenna 8 through the separator 9, so that the radio-frequency signal RF is transmitted from the slot antenna 8.

On the other hand, the receiving unit 7 includes a radio-frequency amplifier 70 according to any of the above-described embodiments, a band-pass filter 71, and a mixer 72, which are connected through slot lines 90, and has a function of converting a radio-frequency signal RF received from the slot antenna 8 to an intermediate-frequency signal IF.

Specifically, the slot antenna 8 receives a radio-frequency signal RF, and the radio-frequency signal RF is input to the input slot line 30 of the radio-frequency amplifier 70 through the separator 9. Then, the radio-frequency amplifier 70 amplifies the radio-frequency signal RF and outputs it from the output slot line 40. The band-pass filter 71 filters the radio-frequency signal RF and outputs it to the mixer 72. The mixer 72 receives this radio-frequency signal RF and a local oscillation signal Lo from the local oscillator 50 through the slot line 90, converts the radio-frequency signal RF into an intermediate-frequency signal IF, and outputs the intermediate-frequency signal IF.

As described above, according to the radio-frequency wireless communication apparatus according to this embodiment, the respective electronic elements are connected through slot lines parallel with each other. With this configuration, the respective elements can be smoothly connected and a signal can be transmitted with low loss by transmitting the signal through the slot lines in a TE mode.

The other configuration, effect, and advantage are substantially the same as those in the above-described first to fifth embodiments, and thus the corresponding description is omitted.

The present invention is not limited to the above-described embodiments, but various modifications or alterations can be accepted within the scope of the present invention.

For example, as shown in FIG. 19, in the radio-frequency amplifier according to the third embodiment, the transistor 2 can be connected to the substrate 1 via through holes 23. That is, the transistor 2 may be placed on the substrate 1 such that the connecting portion 20 of the transistor 2 is oriented to the side opposite to the substrate 1, and the gate electrode G, the drain electrode D, and the both source electrodes S may be electrically connected to the pad portion 10a of the DC electrode 10, the pad portion 11a of the DC electrode 11, and the ground electrode 12, respectively, via the through holes 23 provided at positions corresponding to the gate electrode G, the drain electrode D, and the both source electrodes S.

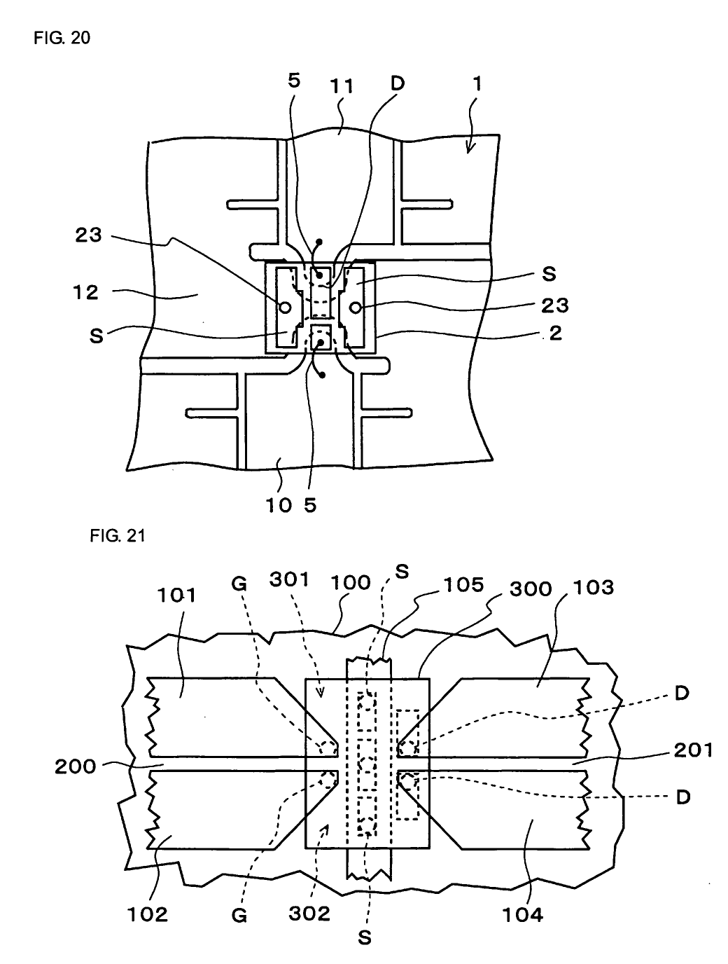

In the radio-frequency amplifier according to the above-described second embodiment, the transistor 2 is connected to the substrate 1 via wires and through holes, as shown in FIG. 10. Alternatively, as shown in FIG. 20, in the radio-frequency amplifier according to the second embodiment, the transistor 2 may be connected to the substrate 1 such that the gate electrode G and the drain electrode D of the transistor 2 are connected to the DC electrodes 10 and 11 via the wires 5 and that the both source electrodes S are connected to the ground electrode 12 via the through holes 23.

In the fifth embodiment, one heat-dissipating through hole 13 is provided. Alternatively, a plurality of heat-dissipating through holes 13 of a small diameter may be dispersed.

In the above-described embodiments, only a case where slot lines are formed on one side of the substrate is described. However, substantially the same effect and advantage as those of the above-described embodiments can be obtained when a PDTL (planar dielectric transmission line) is used.

In the above-described embodiments, a FET is used as the transistor. However, the present invention is not limited to the FET but any type of transistor may be used as long as the transistor is a MOS transistor having a gate electrode, a drain electrode, and a source electrode.

1. A radio-frequency amplifier comprising:
a substrate;
an input-side line portion formed on the substrate and including an input slot line having a shorted end, the input-side line portion inputting an electromagnetic-field-mode signal whose magnetic field is parallel to the input slot line into the input slot line;
an output-side line portion formed on the substrate and including an output slot line arranged substantially parallel to the input slot line, the output slot line having a shorted end; and
a transistor which includes a connecting portion in which source electrodes are arranged on opposite sides of a gate electrode, and a drain electrode arranged along a common line with the gate electrode, wherein the transistor is mounted on the substrate such that the gate electrode is positioned on the input slot line side, the drain electrode is positioned on the output slot line side, and of the gate electrode and the drain electrode are oriented perpendicular to the input slot line and the output slot line.

2. The radio-frequency amplifier according to claim 1,
wherein the input-side line portion includes a first DC cut line which branches off at substantially 90 degrees from the input slot line to a first edge of the substrate, and a second DC cut line which branches off from the input slot line at a second point relative to the first DC cut line to the first edge of the substrate,
wherein the output-side line portion includes a third DC cut line which branches off from the output slot line in a direction opposite to the first DC cut line to a second edge of the substrate, and a fourth DC cut line which branches off from the output slot line at a second point relative to the third DC cut line in a direction opposite to the second DC cut line to the second edge of the substrate, and
wherein the transistor is mounted on the substrate such that the gate electrode of the connecting portion is connected to a first DC electrode separated by the first DC cut line and the second DC cut line of the input-side line portion and that the drain electrode is connected to a second DC electrode separated by the third DC cut line and the fourth DC cut line of the output-side line portion, and such that the source electrodes are connected to a ground electrode separated by the input slot line, the first DC cut line, the output slot line, and the third DC cut line.

3. The radio-frequency amplifier according to claim 1, wherein the gate electrode and the drain electrode of the transistor are arranged a distance of ¼ wavelength from the shorted ends of the input slot line and the output slot line, respectively.

4. The radio-frequency amplifier according to claim 13,
wherein the first and second DC cut lines include stubs that are located ¼ wavelength from branch points of the input slot line, and
wherein the third and fourth DC cut lines include stubs that are located ¼ wavelength from branch points of the output slot line.

5. The radio-frequency amplifier according to claim 1, wherein an air bridge to electrically connect the source electrodes is provided in the connecting portion of the transistor.

6. The radio-frequency amplifier according to claim 2, wherein a part of the input slot line between the first DC cut line and the second DC cut line is curved toward the output slot line side and a part of the output slot line between the third DC cut line and the fourth DC cut line is curved toward the input slot line side so that pad portions are formed on the first and second DC electrodes, and wherein the gate electrode and the drain electrode are connected to the pad portions of the first and second DC electrodes, respectively.

7. The radio-frequency amplifier according to claim 2, wherein the connecting portion of the transistor faces the substrate, and wherein the gate electrode, the drain electrode, and the source electrodes are connected to the first and second DC electrodes and the ground electrode, respectively, using bumps.

8. The radio-frequency amplifier according to claim 2, wherein the gate electrode and the drain electrode are connected to the first and second DC electrodes, respectively, via wires, and wherein the source electrodes are connected to the ground electrode via through holes provided in the transistor.

9. The radio-frequency amplifier according to claim 6, wherein the gate electrode, the drain electrode, and the source electrodes are connected to the pad portions of the first and second DC electrodes and the ground electrode, respectively, via through holes provided in the transistor.

10. The radio-frequency amplifier according to claim 1, wherein one or more heat-dissipating through holes are provided in a portion of the substrate corresponding to a connecting position of the transistor.

11. A radio-frequency wireless communication apparatus comprising:
a mixer to receive an intermediate-frequency signal and a local oscillation signal from a local oscillator through a slot line, convert the intermediate-frequency signal to a radio-frequency signal, and output the radio-frequency signal through a slot line;
a radio-frequency amplifier according to claim 1 to receive the radio-frequency signal from the mixer through the input slot line of the input-side line portion and amplify the signal; and
a slot antenna to transmit the radio-frequency signal output from the output slot line of the output-side line portion of the radio-frequency amplifier.

12. The radio-frequency wireless communication apparatus according to claim 11, further comprising:
a second radio-frequency amplifier according to claim 1 to receive a reception radio-frequency signal received by the slot antenna through the input slot line of the input-side line portion and amplify the reception radio-frequency signal; and
a mixer to receive the reception radio-frequency signal output from the output slot line of the output-side line portion of the second radio-frequency amplifier and a local oscillation signal from the local oscillator through a slot line, convert the radio-frequency signal to an intermediate-frequency signal, and output the intermediate-frequency signal through a slot line.

13. The radio-frequency amplifier according to claim 2, wherein at least one of the first, second, third and fourth DC cut lines has a stub.
